(19) United States
(12) Patent Application Publication
(10) Pub. No.: US 2024/0356523 A1
(43) Pub. Date: Oct. 24, 2024

(54) ACOUSTIC WAVE DEVICE

(71) Applicant: Murata Manufacturing Co., Ltd., Nagaokakyo-shi (JP)

(72) Inventor: Kazuhiro TAKIGAWA, Nagaokakyo-shi (JP)

(21) Appl. No.: 18/630,004

(22) Filed: Apr. 9, 2024

(30) Foreign Application Priority Data
Apr. 21, 2023 (JP) 2023-070077

(51) Int. Cl. H03H 9/145; H03H 9/02; H03H 9/25

(52) U.S. Cl. CPC H03H 9/1457; H03H 9/02637; H03H 9/02889; H03H 9/02992; H03H 9/25

(57) ABSTRACT

In an acoustic wave device, a region where first and second electrode fingers overlap each other is an intersection region including a central region and edge regions facing each other and interposing the central region in a first direction. Each of busbars in the IDT electrode includes reflector busbars in reflector cavities along the second direction. Va≠Vb when an acoustic velocity in the central region is Va and an acoustic velocity in a first cavity containing region is Vb, in a portion where the IDT electrode is provided. Vc≠Vd when an acoustic velocity in the extended central region is Vc and an acoustic velocity in third and fourth cavity containing regions is Vd, in a portion where each of the reflectors is provided. (Vb/Va)≠(Vd/Vc) in the portion where the IDT electrode is provided and in a portion where at least one reflector is provided.

### CROSS REFERENCE TO RELATED APPLICATIONS

This application claims the benefit of priority to Japanese Patent Application No. 2023-070077 filed on Apr. 21, 2023. The entire contents of this application are hereby incorporated herein by reference.

### BACKGROUND OF THE INVENTION

### 1. Field of the Invention

The present invention relates to acoustic wave devices.

### 2. Description of the Related Art

In the related art, acoustic wave devices are widely used as filters of mobile phones and the like. International Publication No. 2015/182522 discloses an example of an acoustic wave device. In the acoustic wave device, an Interdigital Transducer (IDT) is provided on a piezoelectric substrate. In the IDT, a central region, a low acoustic velocity region, and a high acoustic velocity region are disposed in this order from an inner side portion to an outer side portion in a direction in which a plurality of electrode fingers extend. In the direction in which the plurality of electrode fingers extend, a transverse mode is reduced or prevented by disposing regions in which acoustic velocities are different from each other.

### SUMMARY OF THE INVENTION

However, in the acoustic wave device of International Publication No. 2015/182522, there is a concern that it is not possible to sufficiently reduce or prevent an increase in a return loss.

Example embodiments of the present invention provide acoustic wave devices each capable of reducing a return loss.

In a broad aspect of an acoustic wave device according to an example embodiment of the present invention, an acoustic wave device includes a piezoelectric substrate, an IDT electrode on the piezoelectric substrate and including a pair of busbars facing each other, and a plurality of first electrode fingers and a plurality of second electrode fingers, which interdigitate each other, and a pair of reflectors provided on the piezoelectric substrate to face each other and interposing the IDT electrode in a second direction when a direction in which the plurality of first electrode fingers and the plurality of second electrode fingers extend is set as a first direction, and a direction perpendicular or substantially perpendicular to the first direction is set as the second direction, in which each of the reflectors includes a pair of reflector busbars facing each other, and a plurality of reflector electrode fingers electrically connected to the pair of reflector busbars, when the IDT electrode is viewed from the second direction, a region where the first electrode finger and the second electrode finger adjacent to each other overlap each other is an intersection region, the intersection region including a central region and a pair of edge regions facing each other and interposing the central region in the first direction, a region where the central region extends in the second direction is an extended central region, each of the pair of busbars in the IDT electrode and the pair of reflector busbars in each of the reflectors includes a plurality of cavities along the second direction, a region where the plurality of cavities are provided in each of the pair of busbars and the pair of reflector busbars is a cavity containing region, Va≠Vb when, in a portion where the IDT electrode is provided, an acoustic velocity in the central region is set as Va, and an acoustic velocity in the cavity containing region is set as Vb, Vc #Vd when, in a portion where each of the reflectors is provided, an acoustic velocity in the extended central region is set as Vc, and an acoustic velocity in the cavity containing region is set as Vd, and (Vb/Va)≠(Vd/Vc) in the portion where the IDT electrode is provided and in a portion where at least one of the reflectors is provided.

In another broad aspect of an acoustic wave device according to an example embodiment of the present invention, an acoustic wave device includes a piezoelectric substrate, an IDT electrode on the piezoelectric substrate and including a pair of busbars facing each other, and a plurality of first electrode fingers and a plurality of second electrode fingers, which interdigitate each other, and a pair of reflectors provided on the piezoelectric substrate to face each other and interposing the IDT electrode in a second direction when a direction in which the plurality of first electrode fingers and the plurality of second electrode fingers extend is set as a first direction, and a direction perpendicular or substantially perpendicular to the first direction is set as the second direction, in which the reflector includes a pair of reflector busbars facing each other, and a plurality of reflector electrode fingers electrically connected to the pair of reflector busbars, when the IDT electrode is viewed from the second direction, a region where the first electrode finger and the second electrode finger adjacent to each other overlap each other is an intersection region, the intersection region including a central region and a pair of edge regions facing each other and interposing the central region in the first direction, a region where the central region extends in the second direction is an extended central region, each of the pair of busbars in the IDT electrode and the pair of reflector busbars in the reflector includes a plurality of cavities along the second direction, a region where the plurality of cavities are provided in each of the pair of busbars and the pair of reflector busbars is a cavity containing region, Ma≠Mb when a ratio of a portion where the piezoelectric substrate is covered with metal is defined as a metallization ratio in the second direction, and in a portion where the IDT electrode is provided, a metallization ratio in the central region is set as Ma, and a metallization ratio in the cavity containing region is set as Mb, Mc≠Md when, in a portion where each of the reflectors is provided, a metallization ratio in the extended central region is set as Mc, and a metallization ratio in the cavity containing region is set as Md, and (Mb/Ma)≠(Md/Mc) in the portion where the IDT electrode is provided and in a portion where at least one of the reflectors is provided.

According to the acoustic wave devices of example embodiments of the present invention, it is possible to reduce a return loss.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic plan view illustrating an enlarged portion of an IDT electrode in a vicinity of a first busbar and in a vicinity of a second busbar in the first example embodiment of the present invention.

FIG. 3 is a schematic plan view of an acoustic wave device in a comparative example.

FIG. 4 is a diagram illustrating impedance frequency characteristics of the acoustic wave device according to the first example embodiment of the present invention.

FIG. 5 is a diagram illustrating return losses in a vicinity of a resonant frequency of the acoustic wave device in the first example embodiment of the present invention, a modification example of the first example embodiment, and the comparative example.

FIG. 6 is a diagram illustrating return losses in a vicinity of an anti-resonant frequency of the acoustic wave device in the first example embodiment of the present invention, the modification example of the first example embodiment, and the comparative example.

FIG. 7 is a diagram illustrating return losses in a vicinity of an upper end of a stop band of the acoustic wave device in the first example embodiment of the present invention, the modification example of the first example embodiment, and the comparative example.

FIG. 8 is a schematic plan view illustrating an enlarged portion of an IDT electrode in a vicinity of a first busbar and in a vicinity of a second busbar, according to a second example embodiment of the present invention.

FIG. 9 is a schematic plan view of an acoustic wave device according to a third example embodiment of the present invention.

FIG. 10 is a diagram illustrating return losses in a vicinity of a resonant frequency of the acoustic wave device in the third example embodiment of the present invention, a modification example of the third example embodiment, and the comparative example.

FIG. 11 is a diagram illustrating return losses in a vicinity of an anti-resonant frequency of the acoustic wave device in the third example embodiment of the present invention, the modification example of the third example embodiment, and the comparative example.

FIG. 12 is a diagram illustrating return losses in a vicinity of an upper end of a stop band of the acoustic wave device in the third example embodiment of the present invention, the modification example of the third example embodiment, and the comparative example.

FIG. 13 is a schematic plan view of an acoustic wave device according to a fourth example embodiment of the present invention.

FIG. 14 is a schematic plan view of an acoustic wave device according to a fifth example embodiment of the present invention.

FIG. 15 is a schematic plan view of an acoustic wave device according to a sixth example embodiment of the present invention.

FIG. 16 is a schematic plan view of an acoustic wave device according to a seventh example embodiment of the present invention.

FIG. 17 is a schematic plan view of an acoustic wave device according to an eighth example embodiment of the present invention.

FIG. 18 is a schematic plan view of an acoustic wave device according to a ninth example embodiment of the present invention.

FIG. 19 is a schematic cross-sectional view taken along line I-I in FIG. 18.

FIG. 20 is a schematic plan view of an acoustic wave device according to a tenth example embodiment of the present invention.

FIG. 21 is a schematic cross-sectional view taken along line I-I in FIG. 20.

FIG. 22 is a schematic cross-sectional view illustrating a portion corresponding to a cross-section illustrated in FIG. 21, in an acoustic wave device in a modification example of the tenth example embodiment of the present invention.

### DETAILED DESCRIPTION OF THE EXAMPLE EMBODIMENTS

Hereinafter, the present invention will be elucidated by describing specific example embodiments of the present invention with reference to the accompanying drawings.

It should be pointed out that each example embodiment described in the present specification is an example, and partial replacement or combination of configurations is possible between different example embodiments.

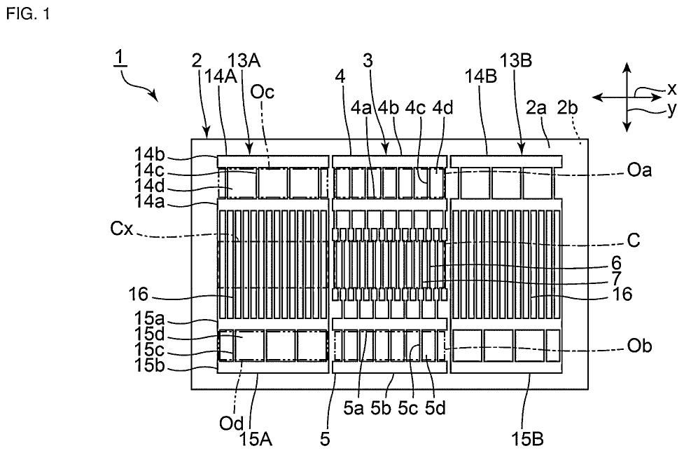

FIG. 1 is a schematic plan view of an acoustic wave device according to a first example embodiment of the present invention.

An acoustic wave device 1 includes a piezoelectric substrate 2. The piezoelectric substrate 2 is a substrate having piezoelectricity. In the present example embodiment, the piezoelectric substrate 2 is a substrate made of only a piezoelectric material. However, the piezoelectric substrate 2 may be a laminated substrate including a piezoelectric layer. In the present example embodiment, lithium niobate is used as the piezoelectric material of the piezoelectric substrate 2. The piezoelectric material is not limited to the above description. For example, lithium tantalate, zinc oxide, aluminum nitride, crystal, PZT (lead zirconate titanate), or the like can also be used.

The piezoelectric substrate 2 includes a first main surface 2a and a second main surface 2b. The first main surface 2a and the second main surface 2b face each other. An IDT electrode 3 is provided on the first main surface 2a of the piezoelectric substrate 2. By applying an AC voltage to the IDT electrode 3, an acoustic wave is excited.

The IDT electrode 3 includes a first busbar 4, a second busbar 5, a plurality of first electrode fingers 6, and a plurality of second electrode fingers 7. The first busbar 4 and the second busbar 5 face each other. The first busbar 4 is connected to each of one ends of the plurality of first electrode fingers 6. The second busbar 5 is connected to each of one ends of the plurality of second electrode fingers 7. The plurality of first electrode fingers 6 and the plurality of second electrode fingers 7 interdigitate each other. In the following description, the first electrode finger 6 and the second electrode finger 7 may be simply referred to as an electrode finger. The first busbar 4 and the second busbar 5 may be simply described as a busbar.

Further, in the following description, a direction in which the plurality of first electrode fingers 6 and the plurality of second electrode fingers 7 extend is set as a first direction y, and a direction perpendicular or substantially perpendicular to the first direction y is set as a second direction x. In the present example embodiment, the second direction x is parallel to an acoustic wave propagation direction.

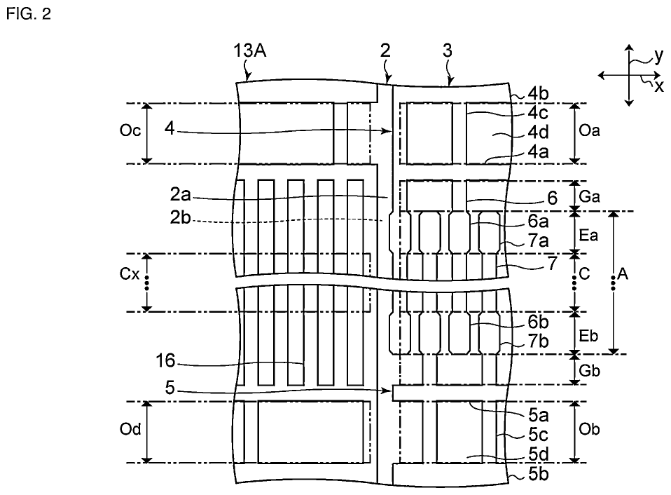

FIG. 2 is a schematic plan view illustrating an enlarged portion of the IDT electrode in the vicinity of the first busbar and in the vicinity of the second busbar in the first example embodiment.

When the IDT electrode 3 is viewed from the second direction x, a region where the first electrode finger 6 and the second electrode finger 7 adjacent to each other overlap each other is an intersection region A. The intersection region A has a central region C and a pair of edge regions. Specifically, the pair of edge regions are a first edge region Ea and a second edge region Eb. The first edge region Ea and the second edge region Eb are disposed to face each other with the central region C interposed between the first edge region Ea and the second edge region Eb in the first direction y. The first edge region Ea is located on the first busbar 4 side. The second edge region Eb is located on the second busbar 5 side.

Returning to FIG. 1, the first busbar 4 is provided with a plurality of cavities 4d along the second direction x. Specifically, the first busbar 4 has an inner busbar portion 4a, an outer busbar portion 4b, and a plurality of connection electrodes 4c. The inner busbar portion 4a and the outer busbar portion 4b are arranged along the first direction y. The inner busbar portion 4a is located at an inner side portion of the cavity 4d and the outer busbar portion 4b in the first direction y. More specifically, the inner busbar portion 4a is located on the intersection region A side of the cavity 4d and the outer busbar portion 4b.

The plurality of connection electrodes 4c are arranged along the second direction x. In the present example embodiment, each connection electrode 4c is parallel or substantially parallel to the first direction y. The inner busbar portion 4a and the outer busbar portion 4b are connected by a plurality of connection electrodes 4c. Each cavity 4d is a cavity surrounded by the inner busbar portion 4a, the two connection electrodes 4c, and the outer busbar portion 4b. Each connection electrode 4c is provided on an extension line of each first electrode finger 6 and is not provided on an extension line of each second electrode finger 7. However, the arrangement of the respective connection electrodes 4c is not limited to the above description.

The second busbar 5 is configured in the similar manner to the first busbar 4. The second busbar 5 is provided with a plurality of cavities 5d along the second direction x. The second busbar 5 includes an inner busbar portion 5a, an outer busbar portion 5b, and a plurality of connection electrodes 4c.

A pair of reflectors 13A and 13B are provided on the piezoelectric substrate 2. The reflector 13A and the reflector 13B are disposed to face each other with the IDT electrode 3 interposed between the reflector 13A and the reflector 13B in the second direction x.

The acoustic wave device 1 has an extended central region Cx. The extended central region Cx is a region obtained by extending the central region C in the second direction x. The extended central region Cx is a region included not only in a portion where the IDT electrode 3 is provided but also in a portion where the pair of reflectors are provided. In FIG. 1, only the extended central region Cx located in the portion where the reflector 13A is provided is illustrated.

The reflector 13A includes a pair of reflector busbars and a plurality of reflector electrode fingers 16. Specifically, the pair of reflector busbars include a first reflector busbar 14A and a second reflector busbar 15A. The first reflector busbar 14A and the second reflector busbar 15A face each other. A plurality of reflector electrode fingers 16 are connected to the first reflector busbar 14A and the second reflector busbar 15A.

Similarly to the first busbar 4 of the IDT electrode 3, the first reflector busbar 14A is provided with a plurality of cavities 14d along the second direction x. Specifically, the first reflector busbar 14A has an inner busbar portion 14a, an outer busbar portion 14b, and a plurality of connection electrodes 14c. The inner busbar portion 14a and the outer busbar portion 14b are arranged along the first direction y. More specifically, the inner busbar portion 14a is located on the plurality of reflector electrode fingers 16 side of the cavity 14d and the outer busbar portion 14b.

The plurality of connection electrodes 14c are arranged along the second direction x. In the present example embodiment, each connection electrode 14c is parallel or substantially parallel to the first direction y. The inner busbar portion 14a and the outer busbar portion 14b are connected by a plurality of connection electrodes 14c. Each cavity 14d is a cavity surrounded by the inner busbar portion 14a, the two connection electrodes 14c, and the outer busbar portion 14b. The connection electrodes 14c are provided on extension lines of every two or more reflector electrode fingers 16, respectively. However, the arrangement of the respective connection electrodes 14c is not limited to the above description.

Similarly, the second reflector busbar 15A is provided with a plurality of cavities 15d along the second direction x. The second reflector busbar 15A has an inner busbar portion 15a, an outer busbar portion 15b, and a plurality of connection electrodes 15c.

In the present example embodiment, the reflector 13B is configured similarly to the reflector 13A. Therefore, the reflector 13B includes a first reflector busbar 14B and a second reflector busbar 15B as a pair of reflector busbars, and a plurality of reflector electrode fingers 16. Each of the first reflector busbar 14B and the second reflector busbar 15B is provided with a plurality of cavities along the second direction x. Each of the first reflector busbar 14B and the second reflector busbar 15B includes an inner busbar portion, an outer busbar portion, and a plurality of connection electrodes. In the following description, the first reflector busbar and the second reflector busbar in each of the reflector 13A and the reflector 13B may be simply referred to as a reflector busbar.

A region where a plurality of cavities are provided in each busbar in the IDT electrode 3 and in each of the reflector busbars of the reflector 13A and the reflector 13B is a cavity containing region. Specifically, a region where the plurality of cavities 4d are provided in the first busbar 4 in the IDT electrode 3 is a cavity containing region Oa. The cavity containing region Oa is a region between the inner busbar portion 4a and the outer busbar portion 4b. A region where the plurality of cavities 5d are provided in the second busbar 5 is a cavity containing region Ob. The cavity containing region Ob is a region between the inner busbar portion 5a and the outer busbar portion 5b.

A region where the plurality of cavities 14d are provided in the first reflector busbar 14A of the reflector 13A is a cavity containing region Oc. The cavity containing region Oc is a region between the inner busbar portion 14a and the outer busbar portion 14b. A region where the plurality of cavities 15d are provided in the second reflector busbar 15A is a cavity containing region Od. The cavity containing region Od is a region between the inner busbar portion 15a and the outer busbar portion 15b. Similarly, each of regions where a plurality of cavities are provided in the pair of reflector busbars of the reflector 13B is also a cavity containing region.

In the following description, in the portion where the IDT electrode 3 is provided, an acoustic velocity in the central region C is set as Va, and an acoustic velocity in each of the cavity containing regions is set as Vb. In the portion where the reflector 13A is provided, an acoustic velocity in the extended central region Cx is set as Vc, and an acoustic velocity in each of the cavity containing regions is set as Vd. Also in the portion where the reflector 13B is provided, an acoustic velocity in the extended central region Cx is set as Vc, and an acoustic velocity in each of the cavity containing regions is set as Vd.

It is pointed out that the reflector 13A and the reflector 13B may be different in the acoustic velocity Vc or the acoustic velocity Vd. However, in the reflector 13A and the reflector 13B of the acoustic wave device 1, the acoustic velocities Vc are the same and the acoustic velocities Vd are the same. Va #Vb in the IDT electrode 3. Vc≠Vd in each of the reflector 13A and the reflector 13B.

A feature of the present example embodiment is that (Vb/Va)≠(Vd/Vc) in the portion where the IDT electrode 3 is provided and each of the portions where the reflector 13A and the reflector 13B are provided. It is sufficient that (Vb/Va)≠(Vd/Vc) in the portion where the IDT electrode 3 is provided and in the portion where at least one reflector is provided. As a result, it is possible to reduce a return loss. Thus, when the acoustic wave device 1 is used in a filter device, it is possible to reduce or prevent an increase in an insertion loss.

In the present example embodiment, the metallization ratio is different between each cavity containing region in the IDT electrode 3 and each cavity containing region in each reflector. As a result, (Vb/Va)≠(Vd/Vc) is established. The details thereof will be described, and the details of the effects described above in the present example embodiment will be described.

In the present specification, the metallization ratio is a ratio of a portion where the piezoelectric substrate 2 is covered with metal in the second direction x. Specifically, for example, the central region C in the portion where the IDT electrode 3 is provided includes a portion where the electrode fingers are provided and a portion where no electrode finger is provided. In other words, the central region C includes a portion where the piezoelectric substrate 2 is covered with the metal forming the electrode finger and a portion where the piezoelectric substrate 2 is not covered. The metallization ratio of the central region C is a ratio of the portion where the piezoelectric substrate 2 is covered with metal to the central region C.

More specifically, a value obtained by dividing the sum of the dimensions of the metal in the central region C along the second direction x by the dimension of the central region C along the second direction x is the metallization ratio in the central region C. The same applies to the extended central region Cx and each cavity containing region.

One end portion of the central region C in the second direction x, in the portion where the IDT electrode 3 is provided, is the center of the electrode finger located in the second direction x on the most one end portion side in the second direction x among the plurality of electrode fingers. The other end portion of the central region C in the second direction x is the center of the electrode finger located in the second direction x on the most other end portion side in the second direction x among the plurality of electrode fingers. In each of the cavity containing region Oa and the cavity containing region Ob, one end portion in the second direction x is a portion overlapping one end portion of the central region C in the second direction x when viewed from the first direction y. In each of the cavity containing region Oa and the cavity containing region Ob, the other end portion in the second direction x is a portion overlapping the other end portion of the central region C in the second direction x when viewed from the first direction y.

One end portion of the extended central region Cx in the second direction x in the portion where the reflector 13A is provided is the center of the reflector electrode finger 16 located in the second direction x on the most one end portion side in the second direction x among the plurality of reflector electrode fingers 16. The other end portion of the extended central region Cx in the second direction x in the portion where the reflector 13A is provided is the center of the reflector electrode finger 16 located in the second direction x on the most other end portion side in the second direction x among the plurality of reflector electrode fingers 16.

In each of the cavity containing region Oc and the cavity containing region Od in the portion where the reflector 13A is provided, one end portion in the second direction x is a portion overlapping one end portion of the extended central region Cx in the second direction x when viewed from the first direction y. In each of the cavity containing region Oc and the cavity containing region Od, the other end portion in the second direction x is a portion overlapping the other end portion of the extended central region Cx in the second direction x when viewed from the first direction y. The same applies to the end portions of each region in the portion where the reflector 13B is provided, in the second direction x.

In the following description, in the portion where the IDT electrode 3 is provided, the metallization ratio in the central region C is set as Ma, and the metallization ratio in each of the cavity containing regions is set as Mb. In the portion where the reflector 13A is provided, the metallization ratio in the extended central region Cx is set as Mc and the metallization ratio in each of the cavity containing regions is set as Md. Also in the portion where the reflector 13B is provided, the metallization ratio in the extended central region Cx is set as Mc and the metallization ratio in each of the cavity containing regions is set as Md.

It is pointed out that the metallization ratios Mc or the metallization ratios Md may be different between the reflector 13A and the reflector 13B. However, in the reflector 13A and the reflector 13B of the acoustic wave device 1, the metallization ratios Mc are the same and the metallization ratios Md are the same. Ma≠Mb in the IDT electrode 3. Mc≠Md in each of the reflector 13A and the reflector 13B.

Here, in each busbar of the IDT electrode 3 and each reflector busbar of each reflector, an inter-center distance between the adjacent connection electrodes in the second direction x is set as a connection electrode pitch. For example, when the connection electrode pitch in the cavity containing region is narrow, the metallization ratio in the cavity containing region is large. Alternatively, when the width of each connection electrode in the cavity containing region is wide, the metallization ratio in this cavity containing region is large. When the metallization ratio in the cavity containing region is large, the acoustic velocity in this cavity containing region is low. The width of the connection electrode is a dimension of the connection electrode along the second direction x.

In the present example embodiment, (Mb/Ma)≠(Md/Mc) in the portion where the IDT electrode 3 is provided and the portion where the reflector 13A is provided. Similarly, (Mb/Ma)≠(Md/Mc) in the portion where the IDT electrode 3 is provided and the portion where the reflector 13B is provided.

Specifically, the connection electrode pitch in the IDT electrode 3 is different from the connection electrode pitch in each of the reflectors. More specifically, the connection electrode pitch in the IDT electrode 3 is narrower than the connection electrode pitch in each of the reflectors. The width of each connection electrode of the IDT electrode 3 is the same as the width of each connection electrode of each reflector. Therefore, Mb>Md. The connection electrode pitch in the IDT electrode 3 may be wider than the connection electrode pitch in each of the reflectors.

Here, an electrode finger pitch in the IDT electrode 3 is an inter-center distance between the first electrode finger 6 and the second electrode finger 7 adjacent to each other in the second direction x. Similarly, in each of the reflectors, an inter-center distance between the reflector electrode fingers 16 adjacent to each other in the second direction x is set as a reflector electrode finger pitch. The electrode finger pitch in the IDT electrode 3 is the same as the reflector electrode finger pitch in each of the reflectors. The width of each electrode finger of the IDT electrode 3 is the same as the width of each reflector electrode finger 16. As a result, Ma=Mc. The width of the electrode finger is a dimension of the electrode finger along the second direction x. The width of the reflector electrode finger 16 is a dimension of the reflector electrode finger 16 along the second direction x.

In the present example embodiment, (Mb/Ma)>(Md/Mc) between the portion where the IDT electrode 3 is provided and the portion where each of the reflectors is provided. However, (Mb/Ma)<(Md/Mc) may be satisfied. In the acoustic wave device 1, the configuration in which (Mb/Ma)≠(Md/Mc) is established is made, so that (Vb/Va)≠(Vd/Vc) is established. It is sufficient that (Mb/Ma)≠(Md/Mc) or (Vb/Va)≠(Vd/Vc) between the portion where the IDT electrode 3 is provided and the portion where at least one reflector is provided.

As described above, in the first example embodiment, it is possible to reduce the return loss. The same applies to a case where the connection electrode pitch in the IDT electrode 3 is wider than the connection electrode pitch in each of the reflectors. An example different from the first example embodiment only in this point is set as a modification example of the first example embodiment. The above effects will be described below by comparing the first example embodiment, the modification example, and a comparative example.

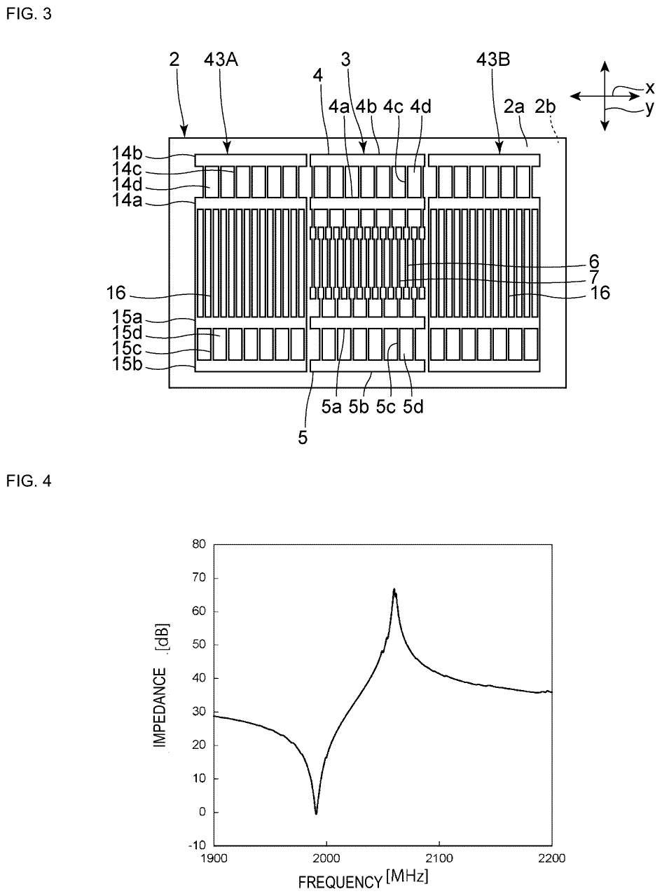

The comparative example is different from the first example embodiment in that, as illustrated in FIG. 3, (Mb/Ma)=(Md/Mc) in a portion where an IDT electrode 3 is provided and a portion where a reflector 43A and a reflector 43B are provided. In other words, the comparative example is different from the first example embodiment in that (Vb/Va)=(Vd/Vc) in the portion where the IDT electrode 3 is provided and each of the portion where the respective reflectors are provided.

As the acoustic wave device 1 of the first example embodiment, an acoustic wave device in which the connection electrode pitch in each of the reflectors is, for example, about 103% of the connection electrode pitch in the IDT electrode 3 was prepared. As an acoustic wave device of the modification example of the first example embodiment, an acoustic wave device in which the connection electrode pitch in each of the reflectors is, for example, about 97% of the connection electrode pitch in the IDT electrode 3 was prepared. On the other hand, in the comparative example, the connection electrode pitch in each of the reflectors is 100% of the connection electrode pitch in the IDT electrode 3. The return loss is compared between the acoustic wave device 1 of the first example embodiment and the acoustic wave device of the comparative example. The results are shown below. The impedance frequency characteristics of the acoustic wave device 1 in the first example embodiment are also shown.

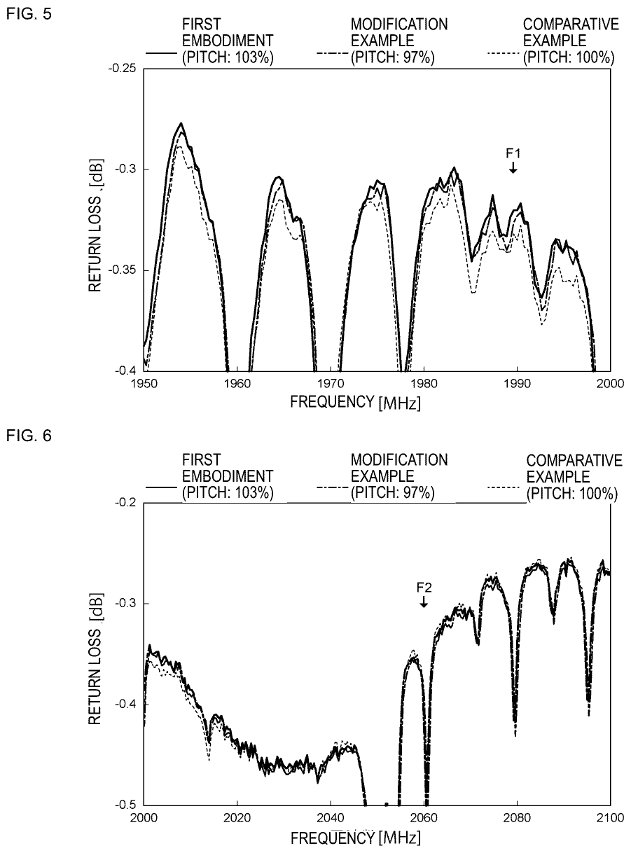

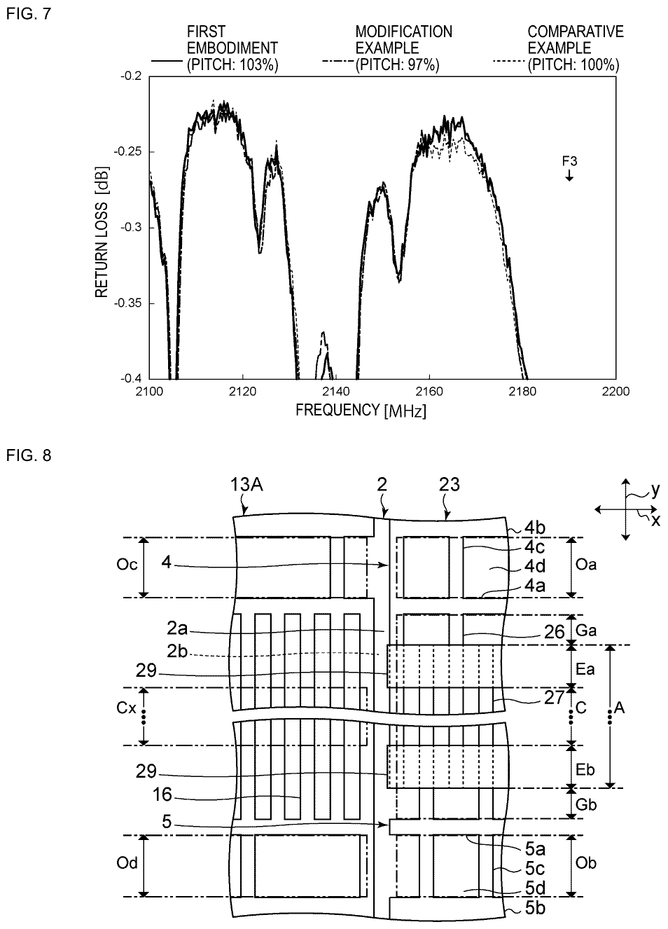

FIG. 4 is a diagram illustrating the impedance frequency characteristics of the acoustic wave device according to the first example embodiment. FIG. 5 is a diagram illustrating the return losses in the vicinity of a resonant frequency of the acoustic wave device in the first example embodiment, the modification example of the first example embodiment, and the comparative example. FIG. 6 is a diagram illustrating the return losses in the vicinity of an anti-resonant frequency of the acoustic wave device in the first example embodiment, the modification example of the first example embodiment, and the comparative example. FIG. 7 is a diagram illustrating the return losses in the vicinity of an upper end of a stop band of the acoustic wave device in the first example embodiment, the modification example of the first example embodiment, and the comparative example. In FIGS. 5 to 7, the connection electrode pitch is simply described as a pitch. The stop band is a region where the wavelength of an acoustic wave is constant by confining the acoustic wave in a metal grating having a periodic structure. The upper end of the stop band is an end portion of the stop band on a high frequency side.

As illustrated in FIG. 4, the resonant frequency of the acoustic wave device 1 in the first example embodiment is near approximately 1990 MHz, for example. The anti-resonant frequency of the acoustic wave device 1 is near approximately 2060 MHz, for example. The frequency of the upper end of the stop band of the acoustic wave device 1 is near approximately 2190 MHz, for example. The resonant frequency, the anti-resonant frequency, and the frequency of the upper end of the stop band in the modification example of the first example embodiment and the comparative example are substantially the same as those in the first example embodiment. In FIG. 5, the resonant frequency is indicated by an arrow F1. In FIG. 6, the anti-resonant frequency is indicated by an arrow F2. In FIG. 7, the frequency of the upper end of the stop band is indicated by an arrow F3.

As illustrated in FIGS. 5 to 7, the absolute values of the return losses of the first example embodiment and the modification example are smaller than the absolute value of the return loss in the comparative example in the vicinity of the resonant frequency, on a lower band side of the anti-resonant frequency, and in the vicinity of the upper end of the stop band. Thus, it is possible to reduce an insertion loss when the acoustic wave device 1 of the first example embodiment is used in a filter device and when the acoustic wave device of the modification example is used as the filter device.

In the first example embodiment, (Vb/Va)≠(Vd/Vc) in the portion where the IDT electrode 3 is provided and in the portion where each of the reflectors is provided. As a result, it is difficult to couple a mode in the cavity containing region in the IDT electrode 3 to a mode in the cavity containing region in each reflector adjacent to this cavity containing region. Specifically, for example, it is difficult to couple a mode in the cavity containing region Oa in the IDT electrode 3 illustrated in FIG. 1 to a mode in the cavity containing region Oc in the reflector 13A. As a result, it is possible to effectively confine the energy of an acoustic wave in the central region C. Therefore, it is possible to reduce the absolute value of the return loss.

Further details of the first example embodiment will be described below.

As illustrated in FIG. 2, a pair of gap regions are located between the intersection region A and the pair of busbars of the IDT electrode 3. Specifically, the pair of gap regions include a first gap region Ga and a second gap region Gb. The first gap region Ga is located on the first busbar 4 side. The second gap region Gb is located on the second busbar 5 side.

Each electrode finger has a widened portion in the first edge region Ea and the second edge region Eb. The width of the electrode finger in the widened portion is wider than the width of the electrode finger in the central region C. More specifically, the first electrode finger 6 has a widened portion 6a in the first edge region Ea. The first electrode finger 6 has a widened portion 6b in the second edge region Eb. Similarly, the second electrode finger 7 has a widened portion 7a in the first edge region Ea. The second electrode finger 7 has a widened portion 7b in the second edge region Eb. As a result, the acoustic velocity in the first edge region Ea and the second edge region Eb is lower than the acoustic velocity in the central region C.

In the first edge region Ea, since each of the plurality of electrode fingers has the widened portion, the average acoustic velocity from the first edge region Ea to the inner busbar portion 4a of the first busbar 4 is low. Thus, a low acoustic velocity region is located in a region including the inner busbar portion 4a of the first busbar 4 from the first edge region Ea. Similarly, a low acoustic velocity region is located in a region including the inner busbar portion 5a of the second busbar 5 from the second edge region Eb. The low acoustic velocity region is a region where the acoustic velocity or the average acoustic velocity is lower than the acoustic velocity Va in the central region C.

Further, the metallization ratio Mc in each of the cavity containing region Oa and the cavity containing region Ob is smaller than the metallization ratio Ma in the central region C. As a result, a high acoustic velocity region is located in each of the cavity containing region Oa and the cavity containing region Ob. The high acoustic velocity region is a region where the acoustic velocity or the average acoustic velocity is higher than the acoustic velocity Va in the central region C.

The central region C, a pair of low acoustic velocity regions, and a pair of high acoustic velocity regions are arranged in this order from the inner side portion to the outer side portion in the first direction y. As a result, a piston mode can be established and a transverse mode can be reduced or prevented.

It is sufficient that at least one electrode finger has a widened portion in the first edge region Ea and the second edge region Eb. However, it is preferable that a plurality of electrode fingers have a widened portion in the first edge region Ea and the second edge region Eb. It is further preferable that all of the electrode fingers have a widened portion. As a result, the piston mode can be more reliably established, and the transverse mode can be more reliably reduced or prevented.

In other example embodiments of the present invention, each electrode finger does not necessarily need to have a widened portion. However, it is preferable that the acoustic wave device has a configuration in which the piston mode can be established. An example of the configuration in which the piston mode can be established, which is different from the first example embodiment, will be described by a second example embodiment.

FIG. 8 is a schematic plan view illustrating an enlarged portion of an IDT electrode in the vicinity of a first busbar and in the vicinity of a second busbar, according to the second example embodiment.

The present example embodiment is different from the first example embodiment in that each electrode finger of the IDT electrode 23 does not have a widened portion, and a pair of mass addition films 29 are provided in a pair of edge regions of an IDT electrode 23. An acoustic wave device in the present example embodiment has the similar configuration to the configuration of the acoustic wave device 1 in the first example embodiment except for the above point.

One mass addition film 29 in the pair of mass addition films 29 is provided in a first edge region Ea. The other mass addition film 29 is provided in a second edge region Eb. Each mass addition film 29 has a band shape. More specifically, each of the mass addition films 29 is continuously provided to overlap a plurality of electrode fingers and a region between the electrode fingers in a plan view. In the present specification, a plan view means viewing the acoustic wave device from the top in a direction perpendicular or substantially perpendicular to the first direction y and the second direction x. More specifically, for example, a first main surface 2a side among the first main surface 2a side and a second main surface 2b side of a piezoelectric substrate 2 is an upward direction in the direction perpendicular or substantially perpendicular to the first direction y and the second direction x.

As illustrated in FIG. 8, since the mass addition film 29 is provided in each edge region, an acoustic velocity in each edge region is lower than an acoustic velocity Va in a central region C. As a result, a low acoustic velocity region is formed, similarly to the first example embodiment. As a result, a piston mode can be established and a transverse mode can be reduced or prevented. As a material of the mass addition film 29, for example, a dielectric such as tantalum oxide can be used.

In the present example embodiment, the mass addition film 29 is provided on the piezoelectric substrate 2 to cover the plurality of electrode fingers. Thus, when viewed in a plan view, in a portion where the mass addition film 29 and the electrode finger overlap each other, the piezoelectric substrate 2, the electrode finger, and the mass addition film 29 are stacked in this order. However, for example, the piezoelectric substrate 2, the mass addition film 29, and the electrode fingers may be stacked in this order. That is, the mass addition film 29 may be provided between the piezoelectric substrate 2 and the electrode finger.

A plurality of mass addition films 29 may be provided in each edge region. In this case, for example, each of the mass addition films 29 may be provided to overlap one electrode finger in a plan view. The mass addition film 29 may be provided on the first electrode finger 26 and on the second electrode finger 27 in contact with each other, or may be provided with a dielectric film or the like interposed therebetween. When one mass addition film 29 is not in contact with both a first electrode finger 26 and a second electrode finger 27, metal may be used as the material of the mass addition film 29.

The mass addition film 29 is provided to overlap at least one electrode finger when viewed in a plan view, in the first edge region Ea and the second edge region Eb. However, when viewed in a plan view, it is preferable that the mass addition film 29 is provided to overlap a plurality of electrode fingers in the first edge region Ea and the second edge region Eb, and it is more preferable that the mass addition film 29 is provided to overlap all the electrode fingers. As a result, the piston mode can be more reliably established, and the transverse mode can be more reliably reduced or prevented.

For example, each electrode finger may have a widened portion, similarly to the first example embodiment. In this case, the low acoustic velocity region may be formed by providing the mass addition film 29.

Also in the present example embodiment, a metallization ratio in a region of the IDT electrode 23 other than each edge region is similar to the metallization ratio in the first example embodiment. Each reflector is configured in the similar manner to that of the first example embodiment. Therefore, (Mb/Ma)≠(Md/Mc) is established in a portion where the IDT electrode 23 is provided and a portion where each reflector is provided. As a result, (Vb/Va)≠(Vd/Vc) is established. Thus, it is possible to reduce the return loss.

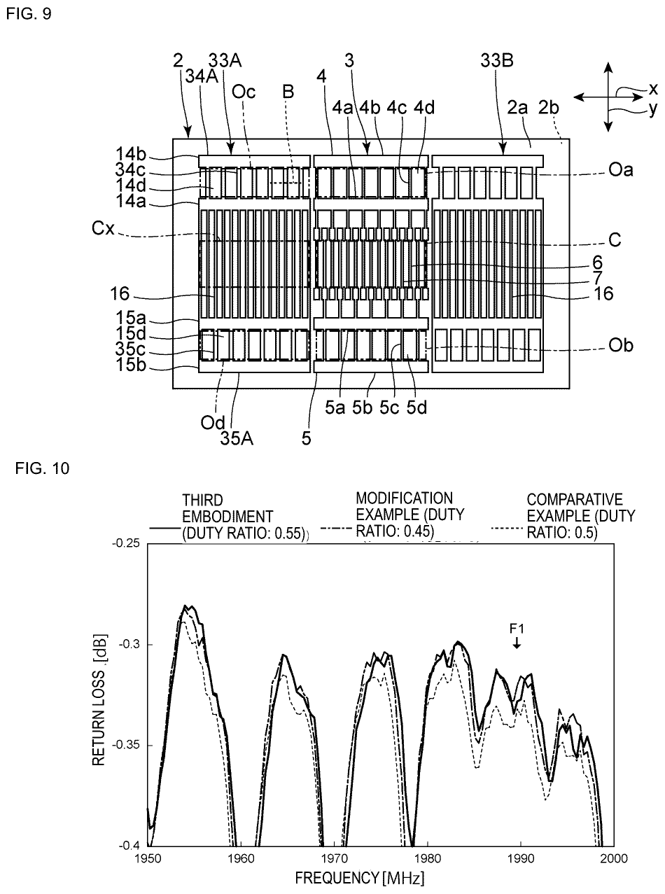

FIG. 9 is a schematic plan view of an acoustic wave device according to a third example embodiment.

The present example embodiment is different from the first example embodiment in that a width of each connection electrode 4c in each busbar of an IDT electrode 3 is different from a width of each connection electrode in each reflector busbar of a reflector 33A. The present example embodiment is different from the first example embodiment in that the width of the connection electrode 4c in each busbar of the IDT electrode 3 is different from a width of each connection electrode in each reflector busbar of a reflector 33B. Further, the present example embodiment is different from the first example embodiment in that a connection electrode pitch in the IDT electrode 3 is the same as a connection electrode pitch in each reflector. An acoustic wave device in the present t example embodiment has the similar configuration to the configuration of the acoustic wave device 1 in the first example embodiment except for the above point.

The width of each connection electrode 4c in the IDT electrode 3 is narrower than the width of each connection electrode 34c in a first reflector busbar 34A of the reflector 33A. The width of each connection electrode 5c in the IDT electrode 3 is narrower than the width of each connection electrode 35c in a second reflector busbar 35A. The connection electrode pitch in the IDT electrode 3 is the same as the connection electrode pitch in the reflector 33A. Thus, a metallization ratio Mb in each cavity containing region in the portion where the IDT electrode 3 is provided is smaller than a metallization ratio Md in each cavity containing region in the portion where the reflector 33A is provided. That is, Mb<Md. The width of each connection electrode in the IDT electrode 3 may be wider than the width of each connection electrode in the reflector 33A.

On the other hand, a metallization ratio Ma in a central region C in the portion where the IDT electrode 3 is provided is the same as a metallization ratio Mc in an extended central region Cx in the portion where the reflector 33A is provided. That is, Ma=Mc. As a result, (Mb/Ma)<(Md/Mc) in the portion where the IDT electrode 3 is provided and the portion where the reflector 33A is provided. The same applies to the portion where the IDT electrode 3 is provided and the portion where the reflector 33B is provided.

In the third example embodiment, (Mb/Ma)≠(Md/Mc) is established in the portion where the IDT electrode 3 is provided and the portion where each reflector is provided. As a result, (Vb/Va)≠(Vd/Vc) is established. Therefore, similarly to the first example embodiment, it is possible to reduce the return loss. The same applies to a case where the width of each connection electrode in the IDT electrode 3 is wider than the width of each connection electrode in each reflector. An example different from the third example embodiment only in this point is set as a modification example of the third example embodiment. The above effects will be described below by comparing the third example embodiment, a modification example of the third example embodiment, and a comparative example.

The comparative example is the comparative example illustrated in FIG. 3. In the comparative example, (Mb/Ma)=(Md/Mc) and (Vb/Va)=(Vd/Vc) in the portion where the IDT electrode 3 is provided and the portion where the reflector 43A and the reflector 43B are provided.

In the present specification, a duty ratio is handled as a parameter in each cavity containing region of the portions where the IDT electrode and the reflector are provided. The duty ratio is a ratio of the portion where the piezoelectric substrate 2 is covered with the connection electrode in the second direction x. Here, the connection electrode pitch is set as p. In the cavity containing region, a virtual line B that extends in the second direction x and has a dimension of 2p is defined. An example of the virtual line B is illustrated in the cavity containing region Oc in FIG. 9. The duty ratio is specifically the ratio of the portion where the piezoelectric substrate 2 is covered with the connection electrode on the virtual line B.

As the acoustic wave device of the third example embodiment, an acoustic wave device in which the duty ratio in each cavity containing region of each reflector is, for example, about 0.55 and the duty ratio in each cavity containing region of the IDT electrode 3 is, for example, about 0.5 was prepared. As the acoustic wave device of the modification example of the third example embodiment, an acoustic wave device in which the duty ratio in each cavity containing region of each reflector is, for example, about 0.45, and the duty ratio in each cavity containing region of the IDT electrode 3 is, for example, about 0.5 was prepared. On the other hand, in the comparative example, the duty ratio in each cavity containing region of each reflector and the duty ratio in each cavity containing region of the IDT electrode 3 are about 0.5, for example. The return loss is compared between the acoustic wave device of the third example embodiment and the acoustic wave device of the comparative example. The results are shown below. The impedance frequency characteristics of the acoustic wave devices in the third example embodiment and the modification example are substantially the same as the impedance frequency characteristics in the first example embodiment illustrated in FIG. 4.

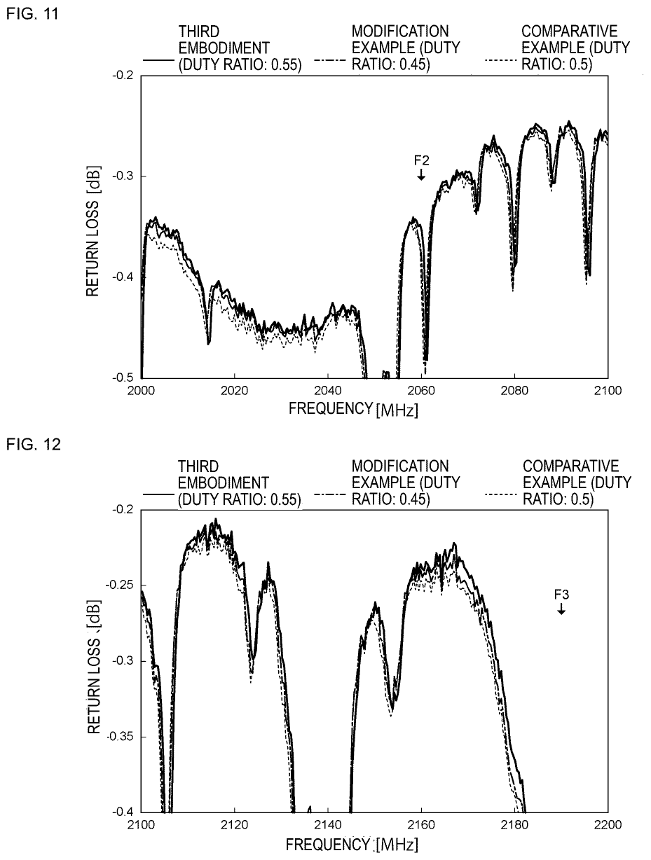

FIG. 10 is a diagram illustrating the return losses in the vicinity of the resonant frequency of the acoustic wave device in the third example embodiment, the modification example of the third example embodiment, and the comparative example. FIG. 11 is a diagram illustrating the return losses in the vicinity of the anti-resonant frequency of the acoustic wave device in the third example embodiment, the modification example of the third example embodiment, and the comparative example. FIG. 12 is a diagram illustrating the return loss in the vicinity of the upper end of the stop band of the acoustic wave device in the third example embodiment, the modification example of the third example embodiment, and the comparative example.

As illustrated in FIGS. 10 to 12, the absolute values of the return losses of the third example embodiment and the modification example are smaller than the absolute value of the return loss in the comparative example in the vicinity of the resonant frequency, in the vicinity of the anti-resonant frequency, and in the vicinity of the upper end of the stop band. Thus, it is possible to reduce an insertion loss when the acoustic wave device of the third example embodiment is used in a filter device and when the acoustic wave device of the modification example is used as the filter device.

Returning to FIG. 9, in the third example embodiment, the connection electrode pitches are the same in the IDT electrode 3 and each of the reflectors. The IDT electrode 3 and the reflector 33A may be different from each other in both the width of the connection electrode and the connection electrode pitch. The IDT electrode 3 and the reflector 33B may be different from each other in both the width of the connection electrode and the connection electrode pitch.

In the first to third example embodiments, (Mb/Ma)≠(Md/Mc) is established in all portions of each cavity containing region of the IDT electrode and in all portions of each cavity containing region of each reflector. However, the present example embodiment is not limited thereto.

Fourth to eighth example embodiments will be described below. The fourth to eighth example embodiments are different from the first example embodiment in that a connection electrode pitch and a duty ratio in each busbar of an IDT electrode and each reflector busbar of each reflector are the same. In the present specification, it is pointed out that the duty ratio is a parameter related to the connection electrode. The fourth to eighth example embodiments are different from the first example embodiment in that a first electrode pattern portion and a second electrode pattern portion, which will be described later, are provided in the fourth to eighth example embodiments. An acoustic wave device in the fourth to eighth example embodiments has the similar configuration to the configuration of the acoustic wave device 1 in the first example embodiment except for the above point.

In the fourth to eighth example embodiments, (Vb/Va)≠(Vd/Vc) is established. As a result, similarly to the first example embodiment, it is possible to reduce the return loss. Therefore, even when the acoustic wave device of each example embodiment is used in a filter device, it is possible to reduce or prevent the increase in the insertion loss.

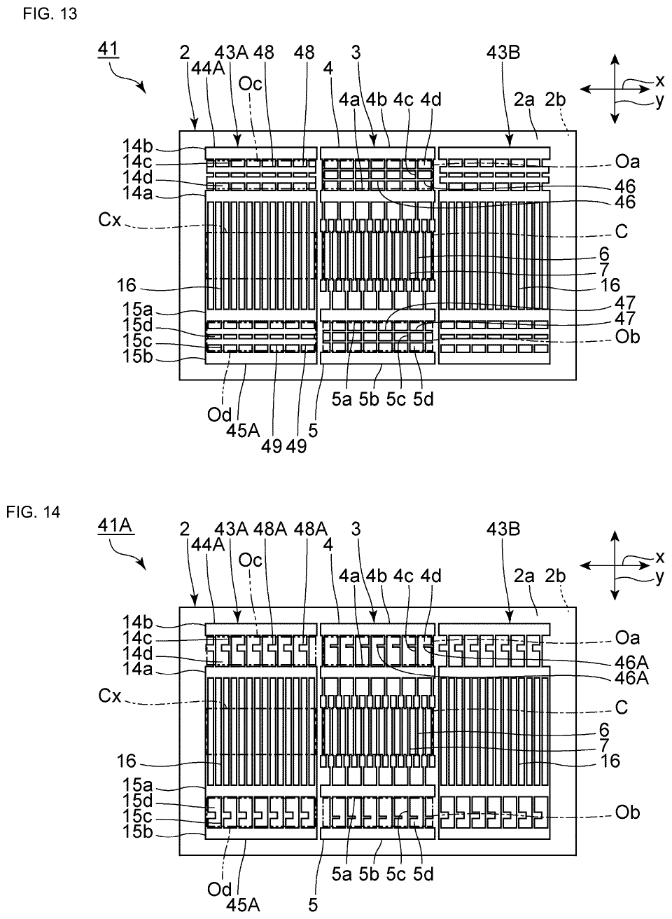

FIG. 13 is a schematic plan view of an acoustic wave device according to the fourth example embodiment.

In the present example embodiment, a plurality of first electrode pattern portions 46 are provided in a cavity containing region Oa in a portion where a first busbar 4 of the IDT electrode 3 is provided. More specifically, each of the first electrode pattern portions 46 extends in the second direction x. Each of the first electrode pattern portions 46 is connected to both of adjacent connection electrodes 4c in the first busbar 4. Some of the plurality of first electrode pattern portions 46 among all the first electrode pattern portions 46 overlap each other when viewed from the second direction x. When the plurality of first electrode pattern portions 46 are set as one row of first electrode pattern portions 46, two rows of first electrode pattern portions 46 are provided in the present example embodiment. The two rows of the first electrode pattern portions 46 are arranged along the first direction y.

As described above, a cavity 4d of the first busbar 4 is a cavity surrounded by an inner busbar portion 4a, two connection electrodes 4c, and an outer busbar portion 4b. In the present example embodiment, two first electrode pattern portions 46 are provided in each cavity 4d. Specifically, in each cavity 4d, two first electrode pattern portions 46 are arranged along the first direction y. As a result, each cavity 4d is divided in the first direction y.

Similarly, a plurality of first electrode pattern portions 47 are provided in a cavity containing region Ob in a portion where the second busbar 5 is provided. Specifically, two rows of first electrode pattern portions 47 are provided.

A plurality of second electrode pattern portions 48 are provided in a cavity containing region Oc in a portion where a first reflector busbar 44A of the reflector 43A is provided. More specifically, each of the second electrode pattern portions 48 extends in the second direction x. Each of the second electrode pattern portions 48 is connected to both of adjacent connection electrodes 14c in the first reflector busbar 44A. Some of the plurality of second electrode pattern portions 48 among all the second electrode pattern portions 48 overlap each other when viewed from the second direction x. When the plurality of second electrode pattern portions 48 are set as one row of second electrode pattern portions 48, two rows of second electrode pattern portions 48 are provided in the present example embodiment. The two rows of the second electrode pattern portions 48 are arranged along the first direction y.

A cavity 14d of the first reflector busbar 44A is a cavity surrounded by an inner busbar portion 14a, two connection electrodes 14c, and an outer busbar portion 14b. In the present example embodiment, two second electrode pattern portions 48 are provided in each cavity 14d. Specifically, in each cavity 14d, two second electrode pattern portions 48 are arranged along the first direction y. As a result, each cavity 14d is divided in the first direction y.

Similarly, a plurality of second electrode pattern portions 49 are provided in a cavity containing region Od in a portion where the second reflector busbar 45A is provided. Specifically, two rows of second electrode pattern portions 49 are provided. Further, similarly, a plurality of second electrode pattern portions are provided in each cavity containing region in a portion where each reflector busbar of the reflector 43B is provided.

An acoustic velocity in a region where the IDT electrode 3 and each reflector are provided depends on the mass added in the region and the like. For example, an acoustic velocity Vb in the cavity containing region Oa in the portion where the first busbar 4 of the IDT electrode 3 is provided depends on an area occupation ratio of a portion where the piezoelectric substrate 2 is covered with metal, in the cavity containing region Oa. Thus, in the present example embodiment, the acoustic velocity Vb depends on the area occupation ratio of the plurality of first electrode pattern portions 46 in the cavity containing region Oa. The same applies to the cavity containing region Ob.

An acoustic velocity Vd in the cavity containing region Oc in the portion where the first reflector busbar 44A of the reflector 43A is provided depends on an area occupation ratio of the portion where the piezoelectric substrate 2 is covered with metal, in the cavity containing region Oc. Thus, in the present example embodiment, the acoustic velocity Vd depends on the area occupation ratio of the plurality of second electrode pattern portions 48 in the cavity containing region Oc. The same applies to the cavity containing region Od. The same applies to each cavity containing region in the portion where each reflector busbar of the reflector 43B is provided.

In an acoustic wave device 41, a dimension of the first electrode pattern portion 46 along the first direction y is different from a dimension of the second electrode pattern portion 48 along the first direction y. Therefore, the area occupation ratio of the plurality of first electrode pattern portions 46 in the cavity containing region Oa is different from the area occupation ratio of the plurality of second electrode pattern portions 48 in the cavity containing region Oc. A dimension of the first electrode pattern portion 47 along the first direction y is different from a dimension of the second electrode pattern portion 49 along the first direction y. Therefore, the area occupation ratio of the plurality of first electrode pattern portions 47 in the cavity containing region Ob is different from the area occupation ratio of the plurality of second electrode pattern portions 49 in the cavity containing region Od. As a result, Vb≠Vd.

On the other hand, the configurations of a central region C in the portion where the IDT electrode 3 is provided and an extended central region Cx in the portion where each of the reflectors is provided are the same as the configurations in the first example embodiment. Therefore, Ma=Mc and Va=Vc. As a result, in the present example embodiment, Vb/Va≠Vd/Vc is established.

In the present example embodiment, the dimension of the first electrode pattern portion 46 along the first direction y is smaller than the dimension of the second electrode pattern portion 48 along the first direction y. However, the dimension of the first electrode pattern portion 46 along the first direction y may be larger than the dimension of the second electrode pattern portion 48 along the first direction y.

The first busbar 4 and the plurality of first electrode pattern portions 46 of the IDT electrode 3 are integrally configured by the same metal. The second busbar 5 and the plurality of first electrode pattern portions 47 are integrally configured by the same metal. However, each busbar and each first electrode pattern portion may be configured by metals different from each other.

Similarly, each reflector busbar of each reflector and the plurality of second electrode pattern portions are integrally configured by the same metal. However, each of the reflector busbars and each of the second electrode pattern portions may be configured by metals different from each other.

As illustrated in FIG. 13, each of the first electrode pattern portions 46 is connected to both the adjacent connection electrodes 4c in the first busbar 4. The first electrode pattern portions 46 adjacent to each other are connected to each other with the connection electrode 4c interposed between the first electrode pattern portions 46. It is sufficient that the first electrode pattern portion 46 is connected to at least one of the adjacent connection electrodes 4c. It is also sufficient that the first electrode pattern portion 47 is connected to at least one of the adjacent connection electrodes 5c in the second busbar 5. Similarly, it is sufficient that each of the second electrode pattern portions is connected to at least one of the adjacent connection electrodes in each reflector busbar.

In the present example embodiment, the connection electrode pitch is the same in the IDT electrode 3 and each of the reflectors. Therefore, the dimension of the first electrode pattern portion along the second direction x is the same as the dimension of the second electrode pattern portion along the second direction x. The dimension of the first electrode pattern portion along the second direction x may be different from the dimension of the second electrode pattern portion along the second direction x.

The number of first electrode pattern portions 46, the number of first electrode pattern portions 47, the number of second electrode pattern portions 48, and the number of second electrode pattern portions 49 in the first direction y is not limited to two. It is sufficient that one first electrode pattern portion or two or more first electrode pattern portions arranged along the first direction y are provided between adjacent connection electrodes in each busbar of the IDT electrode 3. It is sufficient that one second electrode pattern portion or two or more second electrode pattern portions arranged along the first direction y are provided between adjacent connection electrodes in each reflector busbar of each reflector.

Also in the fifth to eighth example embodiments, the plurality of first electrode pattern portions provided in the cavity containing region Oa and the plurality of first electrode pattern portions provided in the cavity containing region Ob are similarly configured. The plurality of second electrode pattern portions provided in each cavity containing region in the portion where each reflector busbar of each reflector is provided are similarly configured. Thus, the configurations of the plurality of first electrode pattern portions provided in the cavity containing region Oa and the plurality of second electrode pattern portions provided in the cavity containing region Oc will be described below in the fifth to eighth example embodiments.

FIG. 14 is a schematic plan view of an acoustic wave device according to the fifth example embodiment.

In the present example embodiment, each first electrode pattern portion 46A provided in the cavity containing region Oa is connected to only one of the adjacent connection electrodes 4c of the first busbar 4. In the cavity containing region Oa, one row of first electrode pattern portions 46A is provided. The first electrode pattern portions 46A adjacent to each other are not connected to each other. The cavity 4d of the first busbar 4 is not divided in the first direction y.

Each second electrode pattern portion 48A provided in the cavity containing region Oc is connected to only one of the adjacent connection electrodes 14c in the first reflector busbar 44A. In the cavity containing region Oc, one row of second electrode pattern portions 48A is provided.

In an acoustic wave device 41A, a dimension of the first electrode pattern portion 46A along the first direction y is different from a dimension of the second electrode pattern portion 48A along the first direction y. A dimension of the first electrode pattern portion 46A along the second direction x is the same as a dimension of the second electrode pattern portion 48A along the second direction x. Therefore, an area occupation ratio of the plurality of first electrode pattern portions 46A in the cavity containing region Oa is different from an area occupation ratio of the plurality of second electrode pattern portions 48A in the cavity containing region Oc. As a result, Vb≠Vd.

On the other hand, Va=Vc in the central region C in the portion where the IDT electrode 3 is provided and the extended central region Cx in the portion where the reflector 43A is provided. Therefore, Vb/Va≠Vd/Vc is established.

In the present example embodiment, the dimension of the first electrode pattern portion 46A along the first direction y is smaller than the dimension of the second electrode pattern portion 48A along the first direction y. However, the dimension of the first electrode pattern portion 46A along the first direction y may be larger than the dimension of the second electrode pattern portion 48A along the first direction y.

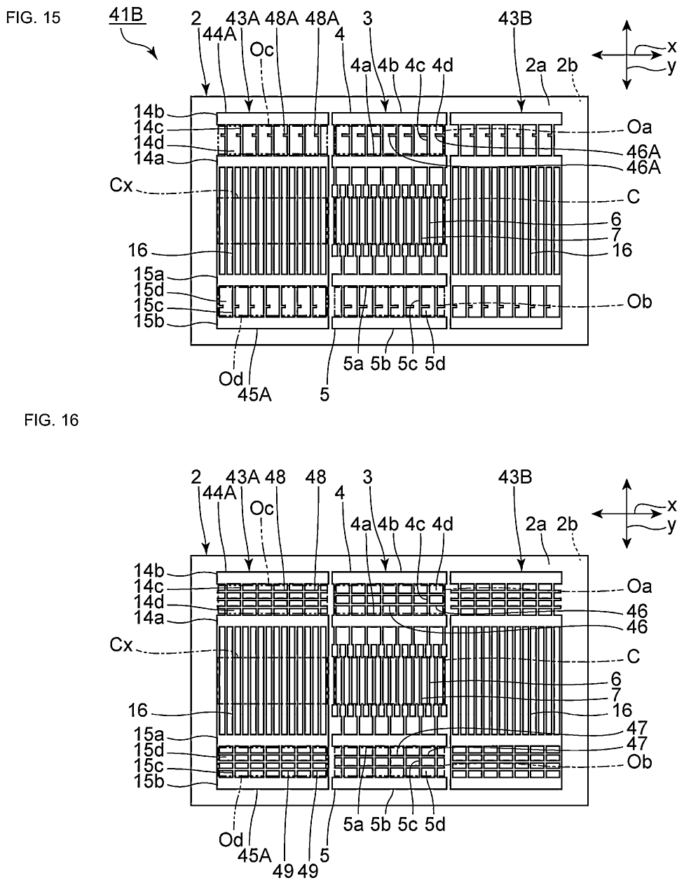

FIG. 15 is a schematic plan view of an acoustic wave device according to the sixth example embodiment.

In the present example embodiment, a plurality of first electrode pattern portions 46A are provided in the cavity containing region Oa, similarly to the fifth example embodiment. Specifically, each first electrode pattern portion 46A provided in the cavity containing region Oa is connected to only one of the adjacent connection electrodes 4c in the first busbar 4. In the cavity containing region Oa, one row of first electrode pattern portions 46A is provided.

Each second electrode pattern portion 48A provided in the cavity containing region Oc is connected to only one of the adjacent connection electrodes 14c in the first reflector busbar 44A. In the cavity containing region Oc, one row of second electrode pattern portions 48A is provided.

In an acoustic wave device 41B, a dimension of the first electrode pattern portion 46A along the second direction x is different from a dimension of the second electrode pattern portion 48A along the second direction x. The dimension of the first electrode pattern portion 46A along the first direction y is the same as a dimension of the second electrode pattern portion 48A along the first direction y. Therefore, an area occupation ratio of the plurality of first electrode pattern portions 46A in the cavity containing region Oa is different from an area occupation ratio of the plurality of second electrode pattern portions 48A in the cavity containing region Oc. As a result, Vb ¥ Vd.

On the other hand, Va=Vc in the central region C in the portion where the IDT electrode 3 is provided and the extended central region Cx in the portion where the reflector 43A is provided. Therefore, Vb/Va≠Vd/Vc is established.

In the present example embodiment, the dimension of the first electrode pattern portion 46A along the second direction x is larger than the dimension of the second electrode pattern portion 48A along the second direction x. However, the dimension of the first electrode pattern portion 46A along the second direction x may be smaller than the dimension of the second electrode pattern portion 48A along the second direction x.

FIG. 16 is a schematic plan view of an acoustic wave device according to the seventh example embodiment.

In the present example embodiment, a plurality of first electrode pattern portions 46 are provided in the cavity containing region Oa, similarly to the fourth example embodiment illustrated in FIG. 13. Specifically, each of the first electrode pattern portions 46 is connected to both the adjacent connection electrodes 4c in the first busbar 4. In the cavity containing region Oa, two rows of first electrode pattern portions 46 are provided.

In the cavity containing region Oc, each second electrode pattern portion 48 is connected to both the adjacent connection electrodes 14c in the first reflector busbar 44A. In the cavity containing region Oc, three rows of second electrode pattern portions 48 are provided. That is, in each cavity 14d, the three second electrode pattern portions 48 are arranged along the first direction y.

In the present example embodiment, the number of first electrode pattern portions 46 provided between the adjacent connection electrodes 4c in the first busbar 4 of the IDT electrode 3 is two. On the other hand, the number of second electrode pattern portions 48 provided between the adjacent connection electrodes 14c in the first reflector busbar 44A of the reflector 43A is three. Thus, the number of first electrode pattern portions 46 provided between the adjacent connection electrodes 4c is different from the number of second electrode pattern portions 48 provided between the adjacent connection electrodes 14c. The dimension of the first electrode pattern portion 46 along the first direction y is the same as a dimension of the second electrode pattern portion 48 along the first direction y. Therefore, an area occupation ratio of the plurality of first electrode pattern portions 46 in the cavity containing region Oa is different from an area occupation ratio of the plurality of second electrode pattern portions 48 in the cavity containing region Oc. As a result, Vb≠Vd.

On the other hand, Va=Vc in the central region C in the portion where the IDT electrode 3 is provided and the extended central region Cx in the portion where the reflector 43A is provided. Therefore, Vb/Va≠Vd/Vc is established.

In the present example embodiment, the number of first electrode pattern portions 46 provided between the adjacent connection electrodes 4c is smaller than the number of second electrode pattern portions 48 provided between the adjacent connection electrodes 14c. However, the number of first electrode pattern portions 46 provided between the adjacent connection electrodes 4c may be larger than the number of second electrode pattern portions 48 provided between the adjacent connection electrodes 14c.

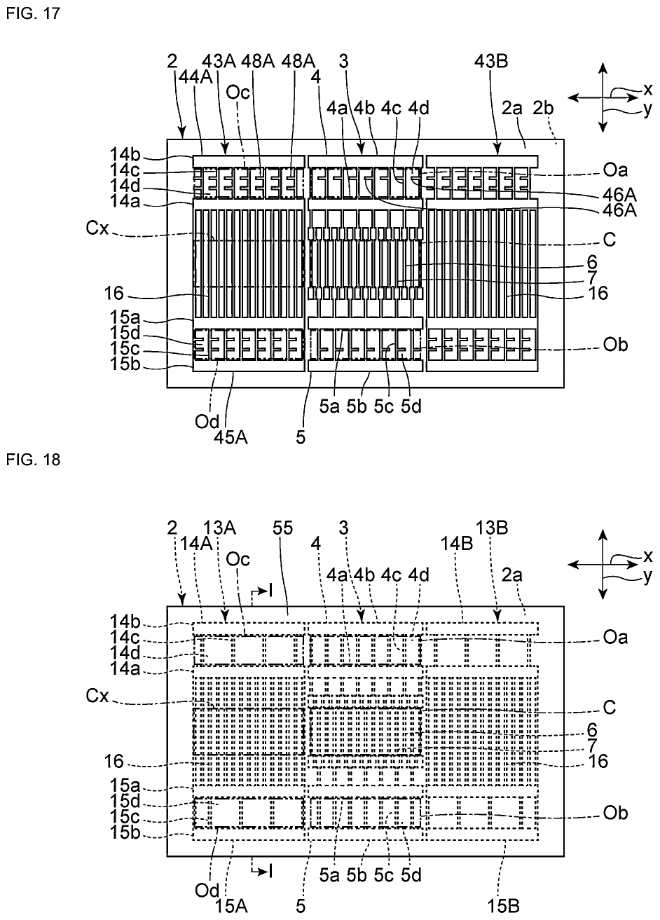

FIG. 17 is a schematic plan view of an acoustic wave device according to the eighth example embodiment.

In the present example embodiment, a plurality of first electrode pattern portions 46A are provided in the cavity containing region Oa, similarly to the fifth example embodiment illustrated in FIG. 14. Specifically, each first electrode pattern portion 46A provided in the cavity containing region Oa is connected to only one of the adjacent connection electrodes 4c in the first busbar 4. In the cavity containing region Oa, one row of first electrode pattern portions 46A is provided.

In the cavity containing region Oc, each second electrode pattern portion 48A is connected to only one of the adjacent connection electrodes 14c in the first reflector busbar 44A. In the cavity containing region Oc, two rows of second electrode pattern portions 48A are provided.

In the present example embodiment, the number of first electrode pattern portions 46A provided between the adjacent connection electrodes 4c in the first busbar 4 of the IDT electrode 3 is one. On the other hand, the number of second electrode pattern portions 48A provided between the adjacent connection electrodes 14c in the first reflector busbar 44A of the reflector 43A is two. Thus, the number of first electrode pattern portions 46A provided between the adjacent connection electrodes 4c is different from the number of second electrode pattern portions 48A provided between the adjacent connection electrodes 14c. The dimension of the first electrode pattern portion 46A along the first direction y is the same as a dimension of the second electrode pattern portion 48A along the first direction y. The dimension of the first electrode pattern portion 46A along the second direction x is the same as the dimension of the second electrode pattern portion 48A along the second direction x. Therefore, an area occupation ratio of the plurality of first electrode pattern portions 46A in the cavity containing region Oa is different from an area occupation ratio of the plurality of second electrode pattern portions 48A in the cavity containing region Oc. As a result, Vb≠Vd.

On the other hand, Va=Vc in the central region C in the portion where the IDT electrode 3 is provided and the extended central region Cx in the portion where the reflector 43A is provided. Therefore, Vb/Va≠Vd/Vc is established.

In the fourth to eighth example embodiments, the example in which, in the first electrode pattern portion and the second electrode pattern portion, any one of the dimension along the first direction y, the dimension along the second direction x, and the number of pieces provided between the adjacent connection electrodes is made be different has been described. However, in the first electrode pattern portion and the second electrode pattern portion, any two or all of the dimension along the first direction y, the dimension along the second direction x, and the number of pieces provided between the adjacent connection electrodes may be made be different. As a result, Vb/Va≠Vd/Vc may be established.

It is sufficient that the area occupation ratio of the plurality of first electrode pattern portions in the cavity containing region of the IDT electrode 3 is different from the area occupation ratio of the plurality of second electrode pattern portions in the cavity containing region of at least one reflector.

However, a dielectric film may be provided on the piezoelectric substrate 2 to cover the IDT electrode 3 and each of the reflectors. This example will be described by a ninth example embodiment.

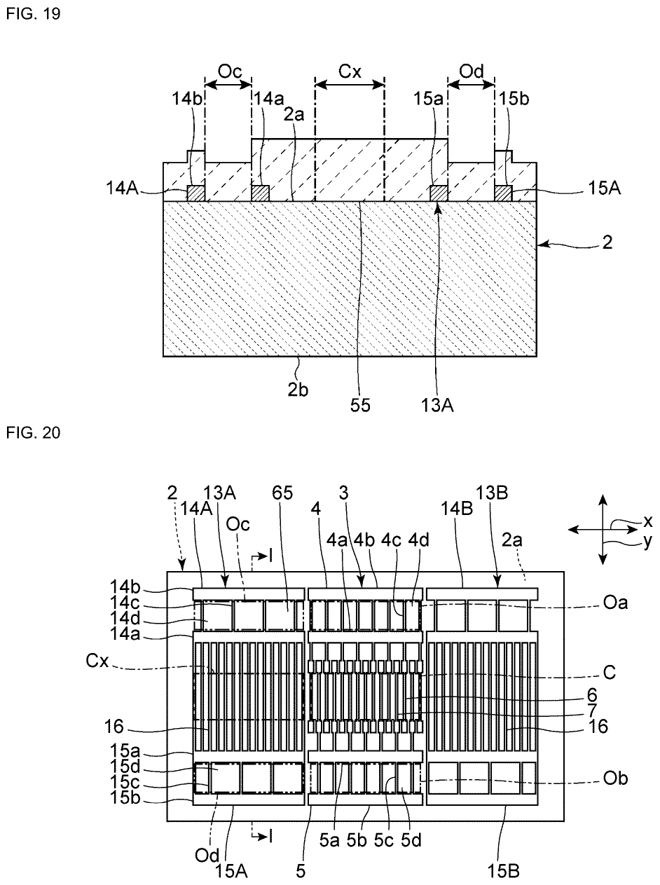

FIG. 18 is a schematic plan view of an acoustic wave device according to the ninth example embodiment. FIG. 19 is a schematic cross-sectional view taken along line I-I in FIG. 18.

As illustrated in FIG. 18, the present example embodiment is different from the first example embodiment in that a dielectric film 55 is provided. Specifically, the dielectric film 55 is provided on a piezoelectric substrate 2 to cover an IDT electrode 3, a reflector 13A, and a reflector 13B. An acoustic wave device in the present example embodiment has the similar configuration to the configuration of the acoustic wave device 1 in the first example embodiment except for the above point.

The dielectric film 55 protects the IDT electrode 3, the reflector 13A, and the reflector 13B. As a result, the IDT electrode 3, the reflector 13A, and the reflector 13B are less likely to be damaged. As a material of the dielectric film 55, for example, silicon oxide, silicon nitride, silicon oxynitride, or the like can be used.

In the present example embodiment, the IDT electrode 3 and each reflector are configured in the similar manner to the first example embodiment. Therefore, (Mb/Ma)≠(Md/Mc) is established in a portion where the IDT electrode 3 is provided and a portion where each reflector is provided. Thus, (Vb/Va)≠(Vd/Vc) is established. Thus, it is possible to reduce the return loss.

As illustrated in FIG. 19, a thickness of a portion that overlaps an extended central region Cx in a plan view, in a portion of the dielectric film 55 that covers the reflector 13A is thicker than a thickness of a portion that overlaps a cavity containing region Oc and a cavity containing region Od in a plan view. The thickness of the portion that overlaps the extended central region Cx in a plan view, in the portion of the dielectric film 55 that covers the reflector 13A may be thinner than the thickness of the portion that overlaps the cavity containing region Oc and the cavity containing region Od in a plan view.

Returning to FIG. 18, the thickness of the portion that overlaps the extended central region in a plan view in the portion of the dielectric film 55 that covers the reflector 13B may be thicker or thinner than the thickness of the portion that overlaps each cavity containing region in a plan view. Alternatively, it is sufficient that, in a portion of the dielectric film 55 that covers at least one reflector, the thickness of the portion that overlaps the extended central region Cx in a plan view is different from the thickness of the portion that overlaps the cavity containing region in a plan view.

In a portion of the dielectric film 55 that covers the IDT electrode 3, a thickness of a portion that overlaps a central region C in a plan view is thicker than a thickness of a portion that overlaps a cavity containing region Oa and a cavity containing region Ob in a plan view. However, in the portion of the dielectric film 55 that covers the IDT electrode 3, the thickness of the portion that overlaps the central region C in a plan view may be thinner than the thickness of the portion that overlaps the cavity containing region Oa and the cavity containing region Ob in a plan view.

As described above, an acoustic velocity in a region where the IDT electrode 3 and each reflector are provided depends on the mass added in the region and the like. For example, the acoustic velocity in this region depends on the thickness of the dielectric film 55 that overlaps this region in a plan view. In the present example embodiment, in the portion where the reflector 13A is provided, the extended central region Cx, and the cavity containing region Oc and the cavity containing region Od are different in a metallization ratio and the thickness of the dielectric film 55, and thus an acoustic velocity Vc is different from an acoustic velocity Vd. The same applies to the portion where the reflector 13B is provided.

Further, in the portion where the IDT electrode 3 is provided, the central region C, and the cavity containing region Oa and the cavity containing region Ob are different in the metallization ratio and the thickness of the dielectric film 55, and thus the acoustic velocity Va is different from the acoustic velocity Vb.

In an example embodiment of the present invention, in the portion where the reflector 13A is provided, the extended central region Cx, and the cavity containing region Oc and the cavity containing region Od may have the same metallization ratio, and may be different in the thickness of the dielectric film 55. Also in this case, Vc≠Vd can be established. The same applies to the portion where the reflector 13B is provided. Further, in the portion where the IDT electrode 3 is provided, the central region C, and the cavity containing region Oa and the cavity containing region Ob may have the same metallization ratio, and may be different in the thickness of the dielectric film 55. Also in this case, Va≠Vb can be established. It is sufficient that (Vb/Va)≠(Vd/Vc) is established.

The configuration in which the dielectric film 55 is provided in the present example embodiment can be applied to the example embodiments of the present invention other than the present example embodiment.

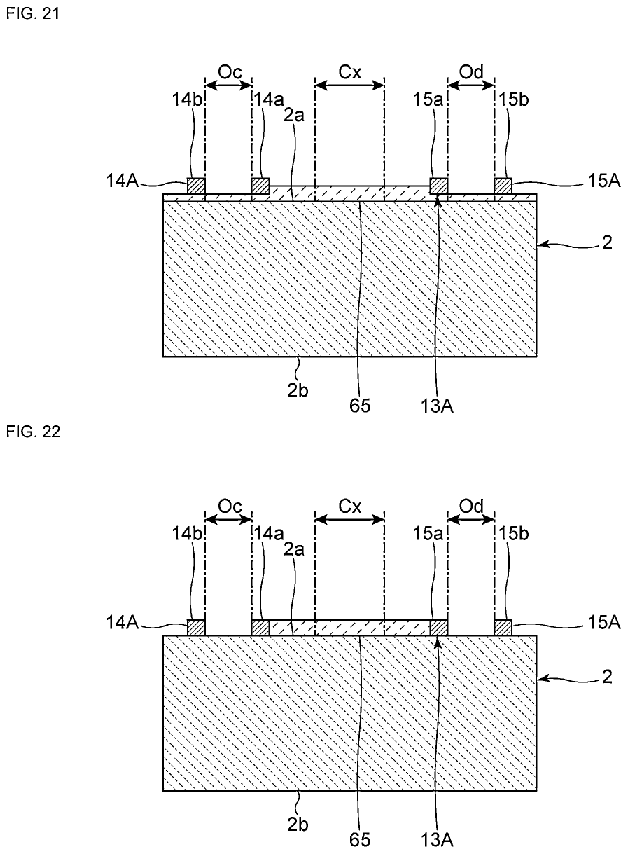

FIG. 20 is a schematic plan view of an acoustic wave device according to a tenth example embodiment. FIG. 21 is a schematic cross-sectional view taken along line I-I in FIG. 20.

As illustrated in FIG. 20, the present example embodiment is different from the first example embodiment in that a dielectric layer 65 is provided between a piezoelectric substrate 2, and an IDT electrode 3 and each reflector. An acoustic wave device in the present example embodiment has the similar configuration to the configuration of the acoustic wave device 1 in the first example embodiment except for the above point.

By adjusting the thickness of the dielectric layer 65, it is possible to easily adjust a specific band of the acoustic wave device. Specifically, it is sufficient that the thickness of the dielectric layer 65 is adjusted in an intersection region A described with reference to FIG. 2. As the material of the dielectric layer 65, for example, silicon oxide or silicon nitride can be used.

In the present example embodiment, the IDT electrode 3 and each reflector are configured in the similar manner to the first example embodiment. Therefore, (Mb/Ma)≠(Md/Mc) is established in a portion where the IDT electrode 3 is provided and a portion where each reflector is provided. Thus, (Vb/Va)≠(Vd/Vc) is established. Thus, it is possible to reduce the return loss.

As illustrated in FIG. 21, a thickness of a portion of the dielectric layer 65, which is located in the extended central region Cx in the portion where the reflector 13A is provided is thicker than a thickness of a portion located in a cavity containing region Oc and a cavity containing region Od. A thickness of a portion of the dielectric layer 65, which is located in the extended central region Cx in the portion where the reflector 13A is provided may be thinner than a thickness of the portion located in the cavity containing region Oc and the cavity containing region Od.

Returning to FIG. 20, the thickness of the portion of the dielectric layer 65, which is located in the extended central region Cx in the portion where the reflector 13B is provided may be thicker or thinner than the thickness of the portion located in each cavity containing region. Alternatively, it is sufficient that the thickness of the portion of the dielectric layer 65, which is located in the extended central region Cx in the portion where at least one reflector is provided is different from the thickness of the portion located in the cavity containing region.

The thickness of the portion of the dielectric layer 65, which is located in the central region C in the portion where the IDT electrode 3 is provided is thicker than the thickness of the portion located in the cavity containing region Oa and the cavity containing region Ob. However, the thickness of the portion of the dielectric layer 65, which is located in the central region C in the portion where the IDT electrode 3 is provided may be thinner than the thickness of the portion located in the cavity containing region Oa and the cavity containing region Ob.

In the present example embodiment, in the portion where the reflector 13A is provided, the extended central region Cx, and the cavity containing region Oc and the cavity containing region Od are different in a metallization ratio and the thickness of the dielectric layer 65, and thus an acoustic velocity Vc is different from an acoustic velocity Vd. The same applies to the portion where the reflector 13B is provided.

Further, in the portion where the IDT electrode 3 is provided, the central region C, and the cavity containing region Oa and the cavity containing region Ob are different in the metallization ratio and the thickness of the dielectric layer 65, and thus the acoustic velocity Va is different from the acoustic velocity Vb.

In an example embodiment of the present invention, in the portion where the reflector 13A is provided, the extended central region Cx, and the cavity containing region Oc and the cavity containing region Od may have the same metallization ratio, and may be different in the thickness of the dielectric layer 65. Also in this case, Vc≠Vd can be established. The same applies to the portion where the reflector 13B is provided. Further, in the portion where the IDT electrode 3 is provided, the central region C, and the cavity containing region Oa and the cavity containing region Ob may have the same metallization ratio, and may be different in the thickness of the dielectric layer 65. Also in this case, Va≠Vb can be established. It is sufficient that (Vb/Va)≠(Vd/Vc) is established.

The configuration in which the dielectric layer 65 is provided in the present example embodiment can be applied to the example embodiments of the present invention other than the present example embodiment.

The thicknesses of the dielectric layer 65 may be made different from each other between the regions by providing the dielectric layer 65 in a certain region and not providing the dielectric layer 65 in other regions. For example, in a modification example of the tenth example embodiment illustrated in FIG. 22, the dielectric layer 65 is not provided in the cavity containing region Oc and the cavity containing region Od in the portion where the reflector 13A is provided. That is, the thickness of the dielectric layer 65 is 0 in these regions. On the other hand, the dielectric layer 65 is provided in the extended central region Cx. As a result, the thickness of the dielectric layer 65 in the extended central region Cx is larger than 0. Therefore, the thickness of the dielectric layer 65 is different in the extended central region Cx, and the cavity containing region Oc and the cavity containing region Od. Although not illustrated, the same applies to a portion where the other reflector is provided.

Furthermore, in the present modification example, in the portion where the IDT electrode is provided, the dielectric layer 65 is not provided in the cavity containing region Oa and the cavity containing region Ob described with reference to FIG. 20. On the other hand, the dielectric layer 65 is provided in the central region C. Thus, the thickness of the dielectric layer 65 is different in the central region C, and the cavity containing region Oa and the cavity containing region Ob. In the present modification example, similarly to the tenth example embodiment, (Vb/Va)≠(Vd/Vc) is established. Thus, it is possible to reduce the return loss.

In the third to tenth example embodiments, the example in which each electrode finger of the IDT electrode has a widened portion has been described, similarly to the first example embodiment. However, as the configuration of the IDT electrode in the third to tenth example embodiments, the same configuration as that in the second example embodiment may be adopted. That is, each electrode finger of the IDT electrode does not need to have a widened portion. In this case, it is preferable that the similar mass addition film to that in the second example embodiment is provided. Alternatively, it is preferable that the mass addition film cited as the example in the description of the second example embodiment is provided. Each electrode finger of the IDT electrode may have a widened portion, and may be provided with the mass addition film. As a result, it is possible to reduced or prevent the transverse mode.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate;
an IDT electrode on the piezoelectric substrate and including a pair of busbars facing each other, and a plurality of first electrode fingers and a plurality of second electrode fingers, which interdigitate each other; and
a pair of reflectors provided on the piezoelectric substrate to face each other and interposing the IDT electrode in a second direction when a direction in which the plurality of first electrode fingers and the plurality of second electrode fingers extend is set as a first direction, and a direction perpendicular or substantially perpendicular to the first direction is set as the second direction; wherein
each of the reflectors includes a pair of reflector busbars facing each other, and a plurality of reflector electrode fingers electrically connected to the pair of reflector busbars;
when the IDT electrode is viewed from the second direction, a region where the first electrode finger and the second electrode finger adjacent to each other overlap each other is an intersection region, the intersection region including a central region and a pair of edge regions facing each other and interposing the central region in the first direction;
a region where the central region extends in the second direction is an extended central region;
each of the pair of busbars in the IDT electrode and the pair of reflector busbars in each of the reflectors includes a plurality of cavities along the second direction;
a region where the plurality of cavities are provided in each of the pair of busbars and the pair of reflector busbars is a cavity containing region;
Va≠Vb when, in a portion where the IDT electrode is provided, an acoustic velocity in the central region is set as Va, and an acoustic velocity in the cavity containing region is set as Vb;
Vc≠Vd when, in a portion where each of the reflectors is provided, an acoustic velocity in the extended central region is set as Vc, and an acoustic velocity in the cavity containing region is set as Vd; and
(Vb/Va)≠(Vd/Vc) in the portion where the IDT electrode is provided and in a portion where at least one of the reflectors is provided.

2. The acoustic wave device according to claim 1, wherein (Mb/Ma)≠(Md/Mc) between the portion where the IDT electrode is provided and a portion where both of the reflectors are provided.

3. The acoustic wave device according to claim 1, wherein
each of the pair of reflector busbars in each of the reflectors includes an inner busbar portion and an outer busbar portion arranged along the first direction, and a plurality of connection electrodes that connect the inner busbar portion and the outer busbar portion and are arranged along the second direction; and
in at least one of the reflectors, an inter-center distance between the reflector electrode fingers adjacent to each other is different from an inter-center distance between the connection electrodes adjacent to each other.

4. The acoustic wave device according to claim 1, wherein
each of the pair of busbars in the IDT electrode and the pair of reflector busbars in each of the reflectors includes an inner busbar portion and an outer busbar portion arranged along the first direction, and a plurality of connection electrodes that connect the inner busbar portion and the outer busbar portion and are arranged along the second direction;
a region between the inner busbar portion and the outer busbar portion is the cavity containing region in each of the pair of busbars in the IDT electrode and the pair of reflector busbars in each of the reflectors;
the acoustic wave device further comprises:
a plurality of first electrode pattern portions that are connected to at least one of the adjacent connection electrodes in the busbar of the IDT electrode and extend in the second direction; and
a plurality of second electrode pattern portions that are connected to at least one of the adjacent connection electrodes in the reflector busbar of each of the reflectors and extend in the second direction; and
an area occupation ratio of the plurality of first electrode pattern portions in the cavity containing region of the IDT electrode is different from an area occupation ratio of the plurality of second electrode pattern portions in the cavity containing region of at least one of the reflectors.

5. The acoustic wave device according to claim 4, wherein a dimension of the first electrode pattern portion in the first direction is different from a dimension of the second electrode pattern portion in the first direction.

6. The acoustic wave device according to claim 4, wherein a dimension of the first electrode pattern portion in the second direction is different from a dimension of the second electrode pattern portion in the second direction.

7. The acoustic wave device according to claim 4, wherein
one of the first electrode pattern portions or two or more of the first electrode pattern portions arranged along the first direction are provided between the adjacent connection electrodes in the busbar of the IDT electrode;
one of the second electrode pattern portions or two or more of the second electrode pattern portions arranged along the first direction are provided between the adjacent connection electrodes in the reflector busbar of the reflector; and
a number of the first electrode pattern portions provided between the adjacent connection electrodes in the busbar of the IDT electrode is different from a number of the second electrode pattern portions provided between the adjacent connection electrodes in the reflector busbar of at least one of the reflectors.

8. The acoustic wave device according to claim 1, further comprising:
a dielectric film provided on the piezoelectric substrate to cover the IDT electrode and each of the reflectors; wherein
in a portion of the dielectric film at which at least one of the reflectors is covered, a thickness of a portion overlapping the extended central region in a plan view is different from a thickness of a portion overlapping the cavity containing region in the plan view.

9. The acoustic wave device according to claim 1, further comprising:
a dielectric layer provided between the piezoelectric substrate, and the IDT electrode and each of the reflectors;
wherein in a portion of the dielectric layer at which at least one of the reflectors is provided, a thickness of a portion located in the extended central region is different from a thickness of a portion located in the cavity containing region.

10. The acoustic wave device according to claim 1, wherein
Va≠Vb when, in the portion where the IDT electrode is provided, the acoustic velocity in the central region is set as Va and an acoustic velocity in the cavity containing region is set as Vb;
Vc≠Vd when, in the portion where each of the reflectors is provided, the acoustic velocity in the extended central region is set as Vc and an acoustic velocity in the cavity containing region is set as Vd; and
(Vb/Va)≠(Vd/Vc) between the portion where the IDT electrode is provided and a portion where both of the reflectors are provided.

11. The acoustic wave device according to claim 1, wherein a low acoustic velocity region in which an acoustic velocity is lower than an acoustic velocity in the central region is located in the pair of edge regions.

12. The acoustic wave device according to claim 11, wherein the low acoustic velocity region is located in the pair of edge regions such that at least one of the plurality of first electrode fingers and the plurality of second electrode fingers has a widened portion having a width that is wider than a width in the central region.

13. The acoustic wave device according to claim 11, wherein the low acoustic velocity region is located in the pair of edge regions such that a mass addition film is provided to overlap at least one of the plurality of first electrode fingers and the plurality of second electrode fingers when viewed in a plan view.

14. An acoustic wave device comprising:
a piezoelectric substrate;
an IDT electrode on the piezoelectric substrate and including a pair of busbars facing each other, and a plurality of first electrode fingers and a plurality of second electrode fingers, which interdigitate each other; and
a pair of reflectors provided on the piezoelectric substrate to face each other and interposing the IDT electrode in a second direction when a direction in which the plurality of first electrode fingers and the plurality of second electrode fingers extend is set as a first direction, and a direction perpendicular or substantially perpendicular to the first direction is set as the second direction; wherein
the reflector includes a pair of reflector busbars facing each other, and a plurality of reflector electrode fingers electrically connected to the pair of reflector busbars;
when the IDT electrode is viewed from the second direction, a region where the first electrode finger and the second electrode finger adjacent to each other overlap each other is an intersection region, the intersection region including a central region and a pair of edge regions facing each other and interposing the central region in the first direction;
a region where the central region extends in the second direction is an extended central region;
each of the pair of busbars in the IDT electrode and the pair of reflector busbars in the reflector includes a plurality of cavities along the second direction;
a region where the plurality of cavities are provided in each of the pair of busbars and the pair of reflector busbars is a cavity containing region;
Ma≠Mb when a ratio of a portion where the piezoelectric substrate is covered with metal is defined as a metallization ratio in the second direction, and in a portion where the IDT electrode is provided, a metallization ratio in the central region is set as Ma, and a metallization ratio in the cavity containing region is set as Mb;
Mc≠Md when, in a portion where each of the reflectors is provided, a metallization ratio in the extended central region is set as Mc, and a metallization ratio in the cavity containing region is set as Md; and
(Mb/Ma)≠(Md/Mc) in the portion where the IDT electrode is provided and in a portion where at least one of the reflectors is provided.

15. The acoustic wave device according to claim 14, wherein (Mb/Ma)≠(Md/Mc) between the portion where the IDT electrode is provided and a portion where both of the reflectors are provided.

16. The acoustic wave device according to claim 14, wherein
each of the pair of reflector busbars in each of the reflectors includes an inner busbar portion and an outer busbar portion arranged along the first direction, and a plurality of connection electrodes that connect the inner busbar portion and the outer busbar portion and are arranged along the second direction; and
in at least one of the reflectors, an inter-center distance between the reflector electrode fingers adjacent to each other is different from an inter-center distance between the connection electrodes adjacent to each other.

17. The acoustic wave device according to claim 14, wherein
each of the pair of busbars in the IDT electrode and the pair of reflector busbars in each of the reflectors includes an inner busbar portion and an outer busbar portion arranged along the first direction, and a plurality of connection electrodes that connect the inner busbar portion and the outer busbar portion and are arranged along the second direction;
a region between the inner busbar portion and the outer busbar portion is the cavity containing region in each of the pair of busbars in the IDT electrode and the pair of reflector busbars in each of the reflectors;
the acoustic wave device further comprises:
a plurality of first electrode pattern portions that are connected to at least one of the adjacent connection electrodes in the busbar of the IDT electrode and extend in the second direction; and
a plurality of second electrode pattern portions that are connected to at least one of the adjacent connection electrodes in the reflector busbar of each of the reflectors and extend in the second direction; and
an area occupation ratio of the plurality of first electrode pattern portions in the cavity containing region of the IDT electrode is different from an area occupation ratio of the plurality of second electrode pattern portions in the cavity containing region of at least one of the reflectors.

18. The acoustic wave device according to claim 17, wherein a dimension of the first electrode pattern portion in the first direction is different from a dimension of the second electrode pattern portion in the first direction.

19. The acoustic wave device according to claim 17, wherein a dimension of the first electrode pattern portion in the second direction is different from a dimension of the second electrode pattern portion in the second direction.

20. The acoustic wave device according to claim 17, wherein
one of the first electrode pattern portions or two or more of the first electrode pattern portions arranged along the first direction are provided between the adjacent connection electrodes in the busbar of the IDT electrode;
one of the second electrode pattern portions or two or more of the second electrode pattern portions arranged along the first direction are provided between the adjacent connection electrodes in the reflector busbar of the reflector; and
a number of the first electrode pattern portions provided between the adjacent connection electrodes in the busbar of the IDT electrode is different from a number of the second electrode pattern portions provided between the adjacent connection electrodes in the reflector busbar of at least one of the reflectors.
